(19) United States
(12) Patent Application Publication
(10) Pub. No.: US 2008/0233490 A1
(43) Pub. Date: Sep. 25, 2008

(54) Mask rework method

(75) Inventor: Sung-Kwon Lee, Kyoungki-do (KR)

Correspondence Address: BLAKELY SOKOLOFF TAYLOR & ZAFMAN LLP, 1279 OAKMEAD PARKWAY, SUNNYVALE, CA, 94085-4040, US

(73) Assignee: Hynix Semiconductor Inc.

(21) Appl. No.: 11/983,290

(22) Filed: Nov. 7, 2007

(30) Foreign Application Priority Data
Mar. 23, 2007 (KR) 2007-0028682

(51) Int. Cl. G03F 1/00

(52) U.S. Cl. 430/5

(57) ABSTRACT

A mask rework method includes forming a first carbon-containing hard mask layer and a first silicon-containing hard mask layer over an etch target layer, forming a first photoresist pattern over the first-silicon-containing hard mask layer, removing the first photoresist pattern, the first silicon-containing hard mask layer, and the first carbon-containing hard mask layer to generate a resulting structure, stacking a second carbon-containing hard mask layer and a second silicon-containing hard mask layer on the resulting structure, and forming a second photoresist pattern over the second silicon-containing hard mask layer.

### CROSS-REFERENCE TO RELATED APPLICATIONS

The present invention claims priority of Korean patent application number 2007-0028682, filed on 23 Mar., 2007, which is incorporated by reference in its entirety.

### BACKGROUND OF THE INVENTION

The present invention relates to a semiconductor device, and more particularly, to a mask rework method.

As semiconductor devices are more highly integrated, the thickness of a photoresist layer in a mask process gradually decreases. Hence, a sufficient etch margin cannot be ensured if using only the photoresist layer and an etching of a lower layer becomes difficult.

Typically, a hard mask is additionally formed for ensuring an etching margin of a photoresist layer.

In the case of amorphous carbon, which is most widely used, amorphous carbon and an anti-reflection layer are sequentially formed. In using amorphous carbon, a heterogeneous polymer hard mask layer is formed in order to prevent the increase of production cost. The heterogeneous polymer hard mask layer has a stacked structure of carbon-rich polymer and silicon-rich polymer.

In patterning a photoresist mask layer, a rework process is performed on an incorrectly patterned photoresist mask layer. Impression may be made on the surface of the heterogeneous polymer hard mask layer disposed under the photoresist mask layer. Therefore, the heterogeneous polymer hard mask layer is also removed in removing the photoresist mask layer.

FIGS. 1A and 1B are cross-sectional views of a typical mask rework method.

Referring to FIG. 1A, a heterogeneous polymer hard mask layer is formed over a semiconductor substrate 11. The heterogeneous polymer hard mask layer has a stacked structure of a carbon-rich hard mask layer 12 and a silicon-rich hard mask layer 13. A photoresist pattern 14 is formed over the silicon-rich hard mask layer 13.

Referring to FIG. 1B, after the patterning process, the photoresist pattern 14, the silicon-rich hard mask layer 13, and the carbon-rich hard mask layer 12 are removed for a rework process. The removing of the photoresist pattern 14, the silicon-rich hard mask layer 13, and the carbon-rich hard mask layer 12 may be performed using an oxygen (O₂) plasma or a thinner removal process.

If the photoresist pattern 14 and the heterogeneous polymer hard mask layer are removed using oxygen at a time, the silicon-rich hard mask layer is oxidized by oxygen to form a silicon oxide (SiOx) layer 15. The silicon oxide layer 15 makes it difficult to remove the photoresist pattern 14 and the heterogeneous polymer hard mask layer.

Further, if the photoresist pattern 14 and the heterogeneous polymer hard mask layer are removed using the thinner removal process, the heterogeneous poly hard mask layer may be damaged when reworking a wafer after inspecting a sampling wafer in an exposure process or measuring a critical dimension (CD) of the wafer.

### SUMMARY OF THE INVENTION

Embodiments of the present invention are directed to providing a mask rework method that can easily remove a heterogeneous polymer hard mask layer when a rework process is performed in a mask process.

In accordance with an aspect of the present invention, there is provided a mask rework method. The method includes forming a first carbon-containing hard mask layer and a first silicon-containing hard mask layer over an etch target layer, forming a first photoresist pattern over the first silicon-containing hard mask layer, removing the first photoresist pattern, the first silicon-containing hard mask layer, and the first carbon-containing hard mask layer to generate a resulting structure, stacking a second carbon-containing hard mask layer and a second silicon-containing hard mask layer on the resulting structure, and forming a second photoresist pattern over the second silicon-containing hard mask layer.

In accordance with another aspect of the present invention, there is provided a mask rework method. The method includes forming a first hard mask layer over an etch target layer, forming a first photoresist pattern over the first hard mask layer, removing the first photoresist pattern and the first hard mask layer using a bottom power, forming a second hard mask layer over the etch target layer, and forming a second photoresist pattern over the second hard mask layer.

### BRIEF DESCRIPTION OF THE DRAWINGS

FIGS. 1A and 1B are cross-sectional views of a typical mask rework method.

FIGS. 2A and 2E are cross sectional views of a mask rework method in accordance with a first embodiment of the present invention.

FIGS. 3A to 3E are cross-sectional views of a mask rework method in accordance with a second embodiment of the present invention.

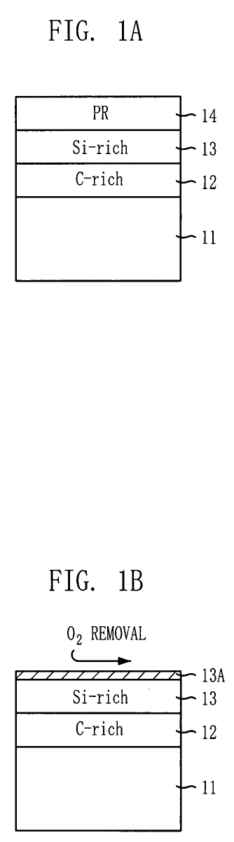

### DESCRIPTION OF SPECIFIC EMBODIMENTS

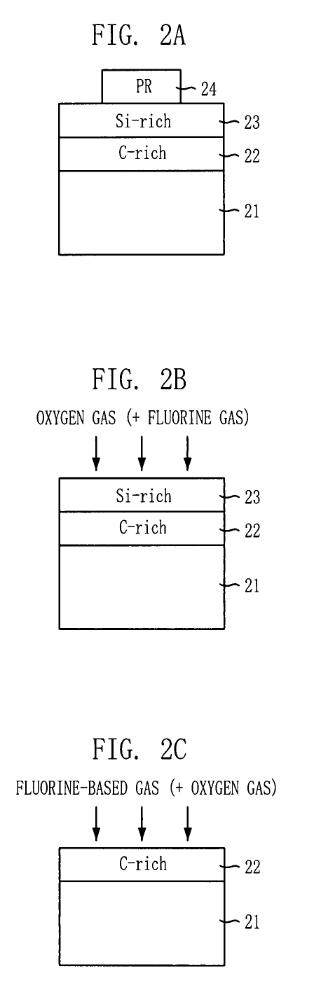

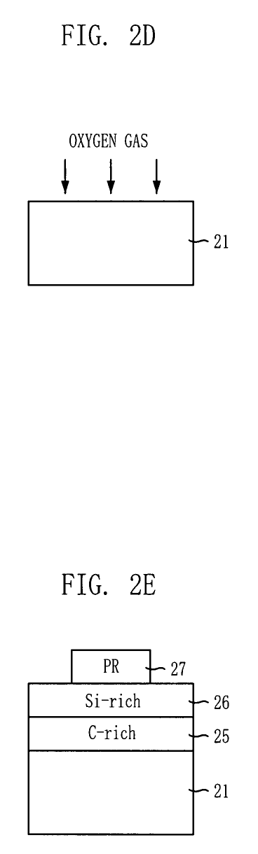

FIGS. 2A and 2E are cross sectional views of a mask rework method in accordance with a first embodiment of the present invention.

Referring to FIG. 2A, a heterogeneous polymer hard mask layer is formed over an etch target layer 21. The heterogeneous polymer hard mask layer has a stacked structure of a carbon-rich hard mask 22 and a silicon-rich hard mask layer 23.

The heterogeneous polymer hard mask layer is formed for ensuring an etch margin of a photoresist pattern and further reducing production cost than amorphous carbon, which is generally used. That is, the amorphous carbon and silicon oxy-nitride (SiON) layer are deposited using a plasma enhanced chemical vapor deposition (PECVD) process. However, production cost considerably increases because of the use of an expensive PECVD apparatus. On the contrary, the heterogeneous polymer hard mask layer can be easily formed using a spin on coating (SOC) method. Therefore, compared with the use of amorphous carbon, production cost is reduced.

Examples of the etch target layer 21 may include a metal layer, a silicon substrate, and a dielectric layer. Also, the nitride layer may be an oxide layer or a nitride layer.

A photoresist pattern 24 is formed over the silicon-rich hard mask layer 23. Before forming the photoresist pattern 24, an anti-reflection layer may be formed for preventing light reflection in exposing the photoresist pattern 24. The anti-reflection layer may include an organic anti-reflection layer such as organic bottom anti-reflection coating (OBARC) layer.

The photoresist pattern 24 is formed by coating a photoresist layer on the silicon-rich hard mask layer 23 and patterning the coated photoresist layer using an exposure process and a development process. When an error occurs in the patterning process, a rework process is necessarily performed on the photoresist layer. If only the photoresist pattern 24 is removed, the silicon-rich hard mask layer 23 may be damaged and a subsequent mask process may be difficult to perform. Therefore, the patterning process can be repeatedly performed after removing the photoresist pattern 24 and the heterogeneous polymer hard mask layers 22 and 23.

As described above, the heterogeneous polymer hard mask layers 22 and 23 can be formed at a low cost compared with amorphous carbon. Thus, the production cost is not greatly influenced even though the heterogeneous polymer hard mask layers are again formed after they are removed in the rework process.

If a typical oxygen removal process is used for removing the photoresist pattern 24 and the heterogeneous polymer hard mask layers 22 and 23 for the rework process, the surface of the silicon-rich hard mask layer 23 is oxidized, thus making it difficult to remove the photoresist pattern 24 and the heterogeneous polymer hard mask layers 22 and 23. In this embodiment of the present invention, the silicon-rich hard mask layer 23 may be removed using a fluorine-based gas. The removal of the photoresist pattern 24 and the heterogeneous polymer hard mask layers 22 and 23 will be described below with reference to FIGS. 2B to 2D.

Referring to FIG. 2B, the photoresist pattern 24 is removed. The photoresist pattern 24 may be removed by oxygen plasma. The photoresist pattern 24 may also be removed by plasma using a gas-mixture including oxygen and fluorine-based gas. The fluorine-based gas comprises one selected from a group consisting of a tetrafluoromethane (CF₄) gas, a hexafluoro-1,3-Butadiene (C₄F₆) gas, a fluoroform (CHF₃) gas, an octafluorocyclopentene (C₅F₈) gas, a perfluoropropane (C₃F₈) gas, a perfluoropropance (C₃F₃) gas, a hexafluorobenzene (C₆F₆) gas, a sulfur hexafluoride (SF₆) gas, a nitrogen trifluoride (NF₃) gas, and a combination thereof.

Referring to FIG. 2C, the silicon-rich hard mask layer 23 is removed. The silicon-rich hard mask layer 23 may be removed using fluorine-based gas or gas-mixture including fluorine-based gas and oxygen. The fluorine-based gas comprises one selected from a group consisting of the CF₄ gas, the C₄F₆ gas, the CHF₃ gas, the C₅F₈ gas, the C₃F₈ gas, the C₃F₃ gas, the C₆F₆ gas, the SF₆ gas, the NF₃ gas, and a combination thereof.

In FIGS. 2B and 2C, the fluorine-based gas used to remove the silicon-rich hard mask layer 23 and the photoresist pattern 24 can easily remove the oxide layer formed when the silicon-rich hard mask layer 23 is oxidized by oxygen during the removal of the photoresist pattern 24. Thus, the manufacturing process is not affected.

Referring to FIG. 2D, the carbon-rich hard mask layer 22 is removed. The carbon-rich hard mask layer 22 may be removed using oxygen plasma.

Referring to FIG. 2E, a heterogeneous organic polymer hard mask layer is formed over the etch target layer 21. The heterogeneous organic polymer hard mask has a stacked structure of a carbon-rich hard mask layer 25 and a silicon-rich hard mask layer 26. A photoresist pattern 27 is formed over the silicon-rich hard mask layer 26.

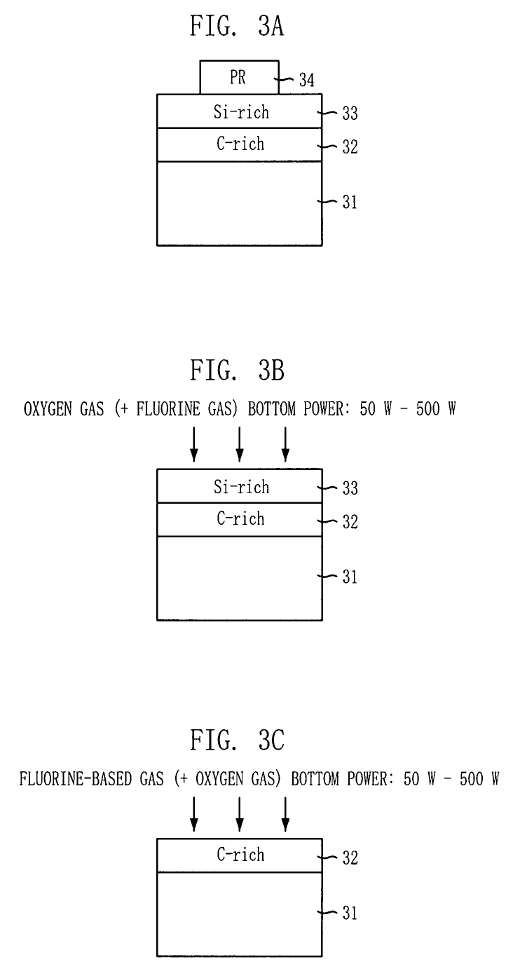

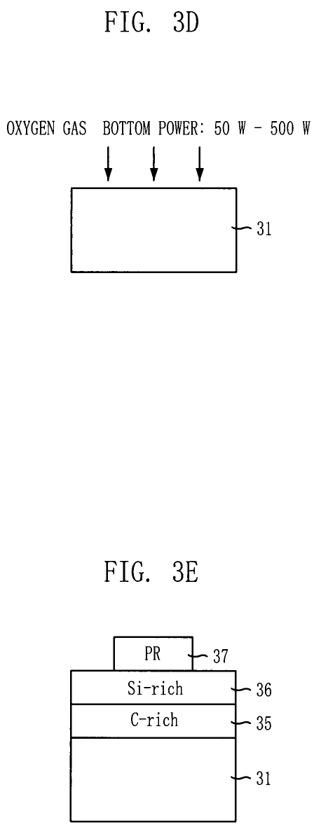

FIGS. 3A to 3E are cross-sectional views of a mask rework method in accordance with a second embodiment of the present invention.

Referring to FIG. 3A, a heterogeneous polymer hard mask layer is formed over an etch target layer 31. The heterogeneous polymer hard mask layer has a stacked structure of a carbon-rich hard mask layer 32 and a silicon-rich hard mask layer 33.

The heterogeneous polymer hard mask layer is formed for ensuring an etch margin of a photoresist pattern and further reducing production cost than amorphous carbon, which is generally used. That is, the amorphous carbon and silicon oxy-nitride (SiON) layer are deposited using a PECVD process. However, production cost considerably increases because of the use of an expensive PECVD apparatus. On the contrary, the heterogeneous polymer hard mask layer can be easily formed using an SOC method. Therefore, compared with the use of amorphous carbon, production cost is reduced.

Examples of the etch target layer 31 may include a metal layer, a silicon substrate, and a dielectric layer. Also, the nitride layer may be an oxide layer or a nitride layer.

A photoresist pattern 34 is formed over the silicon-rich hard mask layer 33. Before forming the photoresist pattern 34, an anti-reflection layer may be formed for preventing light reflection in exposing the photoresist pattern 34. The anti-reflection layer may include an organic anti-reflection layer such as organic bottom anti-reflection coating (OBARC) layer.

The photoresist pattern 34 is formed by coating a photoresist layer on the silicon-rich hard mask layer 33 and patterning the coated photoresist layer using an exposure process and a development process. When an error occurs in the patterning process, a rework process is necessarily performed on the photoresist layer. If only the photoresist pattern 34 is removed, the silicon-rich hard mask layer 33 may be damaged and a subsequent mask process may be difficult to perform. Therefore, the patterning process can be again performed after removing the photoresist pattern 24 and the heterogeneous polymer hard mask layers 32 and 33.

As described above, the heterogeneous polymer hard mask layers 32 and 33 can be formed at a low cost compared with amorphous carbon. Thus, the production cost is not greatly influenced even though the heterogeneous polymer hard mask layers are again formed after they are removed in the rework process.

If a typical oxygen removal process is used for removing the photoresist pattern 34 and the heterogeneous polymer hard mask layers 32 and 33 for the rework process, the surface of the silicon-rich hard mask layer 33 is oxidized, thus making it difficult to remove the photoresist pattern 34 and the heterogeneous polymer hard mask layers 32 and 33. In this embodiment of the present invention, the silicon-rich hard mask layer 33 may be removed using a fluorine-based gas. Alternatively, the silicon-rich hard mask layer 33 may be removed using an etch process by applying a bottom power. The removal of the photoresist pattern 34 and the heterogeneous polymer hard mask layers 32 and 33 will be described below with reference to FIGS. 3B to 3D.

Referring to FIG. 3B, the photoresist pattern 34 is removed. The photoresist pattern 34 may be removed by oxygen plasma. The photoresist pattern 34 may also be removed by plasma using a gas-mixture including oxygen and fluorine-based gas. The fluorine-based gas comprises one selected from a group consisting of the CF₄ gas, the C₄F₆ gas, the CHF₃ gas, the C₅F₈ gas, the C₃F₈ gas, the C₃F₃ gas, the C₆F₆ gas, the SF₆ gas, the NF₃ gas, and a combination thereof.

The removal of the photoresist pattern 34 is performed at a pressure ranging from approximately 10 mT to approximately 100 mT and a source power ranging from approximately 500 W to approximately 2,000 W. At this point, the photoresist pattern 34 can be removed by applying a bottom power ranging from approximately 50 W to approximately 500 W. In this way, when the removal of the photoresist pattern 34 is performed by applying the bottom power, the photoresist pattern 34 can be more easily removed in a concept of a light etch process, not a removal process.

Referring to FIG. 3C, the silicon-rich hard mask layer 33 is removed. The silicon-rich hard mask layer 33 may be removed using fluorine-based gas or a gas-mixture including fluorine-based gas and oxygen. The fluorine-based gas comprises one selected from a group consisting of the CF₄ gas, the C₄F₆ gas, the CHF₃ gas, the C₅F₈ gas, the C₃F₈ gas, the C₃F₃ gas, the C₆F₆ gas, the SF₆ gas, the NF₃ gas and a combination thereof.

The silicon-rich hard mask layer 33 may be removed in the same conditions as described with reference to FIG. 3B. That is the silicon-rich hard mask layer 33 may be removed at a pressure ranging from approximately 10 mT to approximately 100 mT, a source power ranging from approximately 500 W to approximately 2,000 W, and a bottom power ranging from approximately 50 W to approximately 500 W.

In FIGS. 3B and 3C, the fluorine-based gas used to remove the silicon-rich hard mask layer 33 and the photoresist pattern 34 can easily remove the oxide layer formed when the silicon-rich hard mask layer 33 is oxidized by oxygen during the removal of the photoresist pattern 34. Thus, the manufacturing process is not affected. Further, the oxide layer can be more easily performed because the light etch process is performed by applying the bottom power ranging from approximately 50 W to approximately 500 W.

Referring to FIG. 3D, the carbon-rich hard mask layer 32 is removed. The carbon-rich hard mask layer 32 may be removed using oxygen plasma. The carbon-rich hard mask layer 32 may be removed in the same conditions as described with reference to FIG. 3B. That is, the carbon-rich hard mask layer 32 may be removed at a pressure ranging from approximately 10 mT to approximately 100 mT, a source power ranging from approximately 500 W to approximately 2,000 W, and a bottom power ranging from approximately 50 W to approximately 500 W.

Referring to FIG. 3E, a heterogeneous organic polymer hard mask layer is formed over the etch target layer 31. The heterogeneous organic polymer hard mask layer has a stacked structure of a carbon-rich hard mask layer 35 and a silicon-rich hard mask layer 36. A photoresist pattern 37 is formed over the silicon-rich hard mask layer 36.

In the mask process using the heterogeneous polymer hard mask layer for ensuring the etch margin of the photoresist pattern and reducing production cost, the silicon-rich hard mask layer 33, in which the oxide layer may be formed by oxygen gas during the removal of the photoresist pattern 24, is removed using a fluorine-based gas. Thus, the hard mask layers 32 and 33 can be easily removed, regardless of the oxidation of the silicon-rich hard mask layer 33 or the damage of the hard mask layers 32 and 33.

Further, in removing the photoresist pattern 34, the silicon-rich hard mask layer 33, and the carbon-rich hard mask layer 32, the light etch process is performed by applying the bottom power, in addition to the fluorine-based gas. Thus, the hard mask layers 32 and 33 can be easily removed, regardless of the oxidation of the silicon-rich hard mask layer 33 or the damage of the hard mask layers 32 and 33.

The mask rework methods in accordance with the embodiments of the present invention can be easily performed in the mask process using the heterogeneous polymer hard mask layer.

While the present invention has been described with respect to the specific embodiments, it will be apparent to those skilled in the art that various changes and modifications may be made without departing from the spirit and scope of the invention as defined in the following claims.

What is claimed is:

1. A mask rework method, comprising:
forming a first carbon-containing hard mask layer and a first silicon-containing hard mask layer over an etch target layer;
forming a first photoresist pattern over the first silicon-containing hard mask layer;
removing the first photoresist pattern, the first silicon-containing hard mask layer, and the first carbon-containing hard mask layer to generate a resulting structure,
stacking a second carbon-containing hard mask layer and a second silicon-containing hard mask layer on the resulting structure; and
forming a second photoresist pattern over the second silicon-containing hard mask layer.

2. The mask rework method of claim 1, wherein removing the first silicon-containing hard mask layer comprises using one of a fluorine-based gas and a gas-mixture including a fluorine-based gas and an oxygen gas.

3. The mask rework method of claim 1, wherein removing the first photoresist pattern comprises using one of an oxygen gas and a gas-mixture including an oxygen gas and a fluorine-based gas.

4. The mask rework method of claim 1, wherein removing the first carbon-containing hard mask layer comprises using an oxygen gas.

5. The mask rework method of claims 2, wherein the fluorine-based gas comprises one selected from a group consisting of tetrafluoromethane (CF₄) gas, a hexafluoro-1,3-Butadiene (C₄F₆) gas, a fluoroform (CHF₃) gas, an octafluorocyclopentene (C₅F₈) gas, a perfluoropropane (C₃F₈) gas, a perfluoropropance (C₃F₃) gas, a hexafluorobenzene (C₆F₆) gas, a sulfur hexafluoride (SF₆) gas, a nitrogen trifluoride (NF₃) gas, and a combination thereof.

6. The mask rework method of claim 1, wherein the first carbon-containing hard mask layer and the first silicon-containing hard mask layer are formed by performing a spin on coating (SOC) method.

7. The mask rework method of claim 1, wherein the etch target layer comprises one of a metal layer, a silicon substrate, an oxide-based layer, and a nitride-based layer.

8. A mask rework method, comprising:
forming a first hard mask layer over an etch target layer;
forming a first photoresist pattern over the first hard mask layer;
removing the first photoresist pattern and the first hard mask layer using a bottom power;
forming a second hard mask layer over the etch target layer; and
forming a second photoresist pattern over the second hard mask layer.

9. The mask rework method of claim 8, wherein the bottom power ranges from approximately 50 W to approximately 500 W.

10. The mask rework method of claim 8, wherein each of the first and the second hard mask layers is formed as a stack structure including one or both of a carbon-containing hard mask layer and a silicon-containing hard mask layer.

11. The mask rework method of claim 8, wherein removing the first hard mask layer comprises using one of a fluorine-based gas and a gas-mixture including a fluorine-based gas and an oxygen gas.

12. The mask rework method of claim 8, wherein removing the first hard mask layer comprises using an oxygen gas.

13. The mask rework method of claim 8, wherein removing the first photoresist pattern comprises using one of an oxygen gas and a gas-mixture including an oxygen gas and a fluorine-based gas.

14. The mask rework method of claim 11, wherein the fluorine-based gas comprises one selected from a group consisting of the CF₄ gas, the C₄F₆ gas, the CHF₃ gas, the C₅F₈ gas, the C₃F₈ gas, the C₃F₃ gas, the C₆F₆ gas, the SF₆ gas, the NF₃ gas, and a combination thereof.

15. The mask rework method of claim 8, wherein the etch target layer comprises one of a metal layer, a silicon substrate, an oxide-based layer, and a nitride-based layer.

16. The mask rework method of claim 8, wherein removing the first photoresist pattern and the first hard mask layer comprises using a pressure ranging from approximately 10 mT to approximately 100 mT and a source power ranging from approximately 500 W to approximately 2,000 W.
